(19) United States
(12) Patent Application Publication
(10) Pub. No.: US 2025/0087545 A1
(43) Pub. Date: Mar. 13, 2025

(54) Semiconductor Device and Method of Forming FOWLP with Pre-Molded Embedded Discrete Electrical Component

(71) Applicant: STATS ChipPAC Pte. Ltd., Singapore (SG)

(72) Inventors: Kai Chong Chan, Singapore (SG); Linda Pei Ee Chua, Singapore (SG); Yung Kuan Hsiao, Singapore (SG); Beng Yee Teh’, Singapore (SG); Jian Zuo, Singapore (SG); Yaojian Lin, Jiangyin (CN)

(73) Assignee: STATS ChipPAC Pte. Ltd., Singapore (SG)

(21) Appl. No.: 18/462,612

(22) Filed: Sep. 7, 2023

(51) Int. Cl. H01L 23/31; H01L 21/56; H01L 23/00; H01L 23/498

(52) U.S. Cl. CPC H01L 23/3157; H01L 21/563; H01L 21/565; H01L 23/49816; H01L 24/06; H01L 24/30; H01L 2224/0603; H01L 2224/06051; H01L 2224/3003; H01L 2224/30051; H01L 2224/30104

(57) ABSTRACT

A semiconductor device has a pre-molded discrete electrical component and a first encapsulant deposited over the pre-molded discrete electrical component. A first conductive layer is formed over the first encapsulant and pre-molded discrete electrical component. An electrical component is disposed over the first conductive layer. A second encapsulant is deposited over the electrical component and first conductive layer. A second conductive layer is formed over the second encapsulant. A conductive pillar is formed between the first conductive layer and second conductive layer through the second encapsulant. The pre-molded discrete electrical component has a discrete component and a third encapsulant deposited around the discrete component. The discrete component has an electrical terminal, a finish formed over the electrical terminal, and a third conductive layer formed over the finish. An interconnect structure formed on the electrical component is oriented toward the first conductive layer or the second conductive layer.

### FIELD OF THE INVENTION

The present invention relates in general to semiconductor devices and, more particularly, to a semiconductor device and method of forming a FoWLP with pre-molded and embedded discrete electrical component.

### BACKGROUND OF THE INVENTION

Semiconductor devices are commonly found in modern electrical products. Semiconductor devices perform a wide range of functions, such as signal processing, high-speed calculations, transmitting and receiving electromagnetic signals, controlling electrical devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices often contain a semiconductor die or substrate with electrical interconnect structures, e.g., redistribution layers (RDL) formed over one or more surfaces of the semiconductor die or substrate to perform necessary electrical functions. The semiconductor devices are formed on wafers or panels, such as molded reconstituted wafer level package (WLP) or fan-out wafer level package (FoWLP). The WLP often uses discrete passive and/or active components for electrical function, such as radio frequency (RF) signal transmission. These discrete passive and active components are exposed and subject to delamination at the electrical connection terminals to the RDL due to circuit topology.

### BRIEF DESCRIPTION OF THE DRAWINGS

FIGS. 1a-1c illustrate a semiconductor wafer with a plurality of semiconductor die separated by a saw street;

FIGS. 2a-2h illustrate a process of forming a pre-molded embedded discrete electrical component;

FIG. 3 illustrates another pre-molded embedded discrete electrical component;

FIGS. 4a-4b illustrate attaching the pre-molded embedded discrete electrical component to a carrier;

FIGS. 5a-5c illustrate another pre-molded embedded discrete electrical component attached to a carrier;

FIGS. 6a-6n illustrate a first embodiment of a FoWLP with a pre-molded embedded discrete electrical component;

FIGS. 7a-7f illustrate a second embodiment of a FoWLP with a pre-molded embedded discrete electrical component;

FIGS. 8a-8e illustrate a third embodiment of a FoWLP with a pre-molded embedded discrete electrical component; and

FIG. 9 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

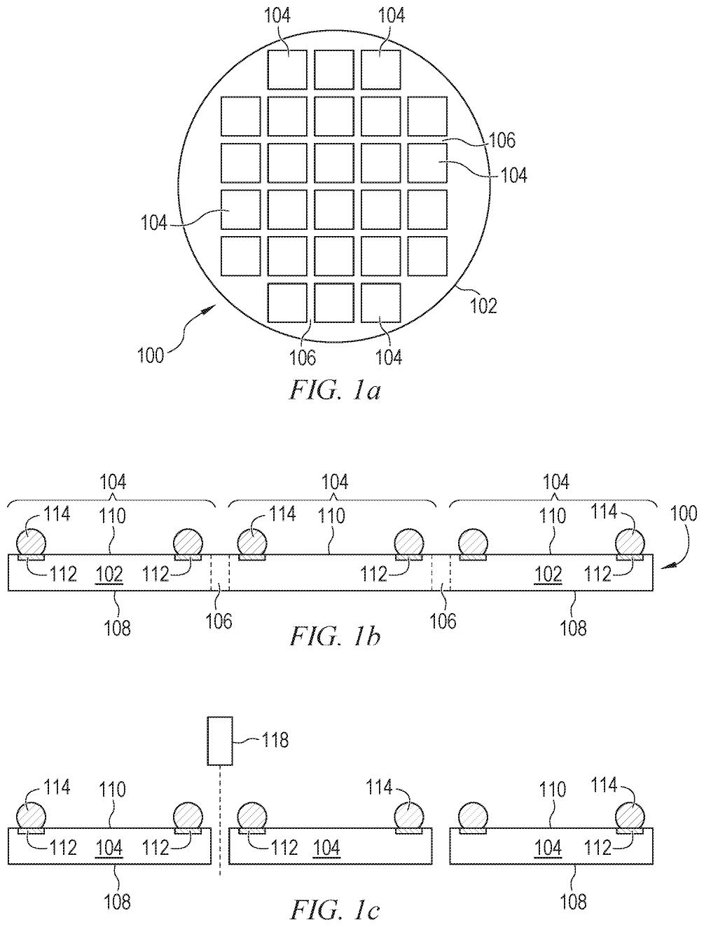

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit.

Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

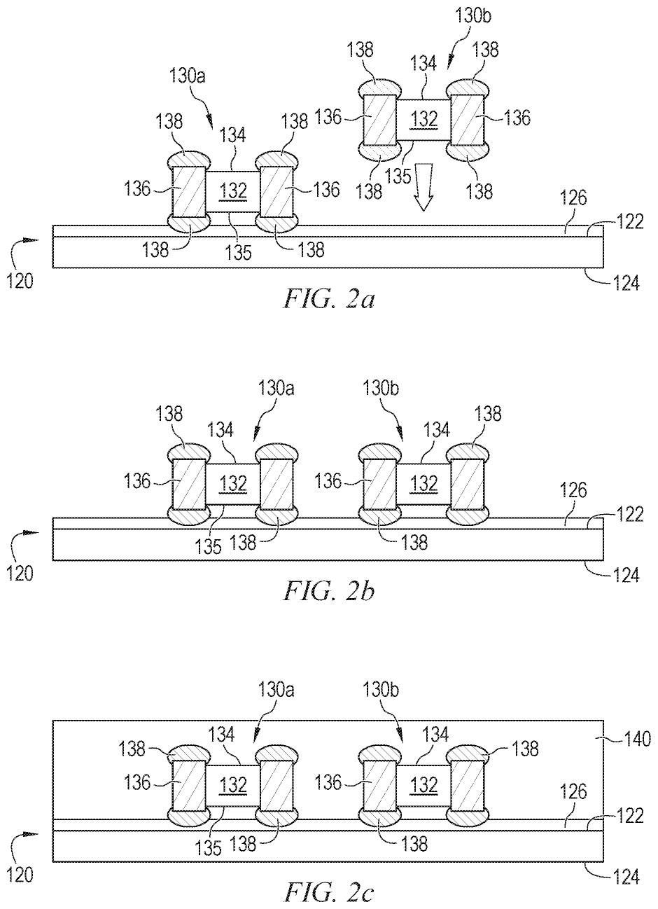

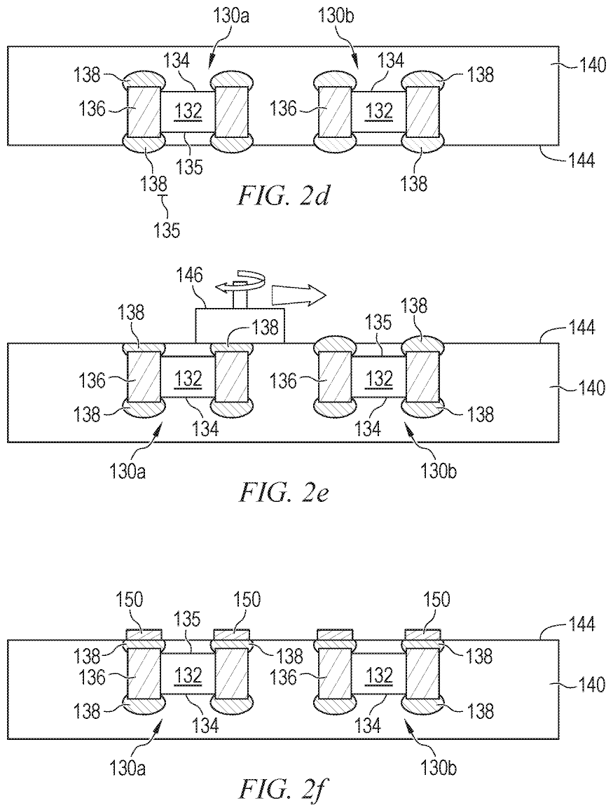

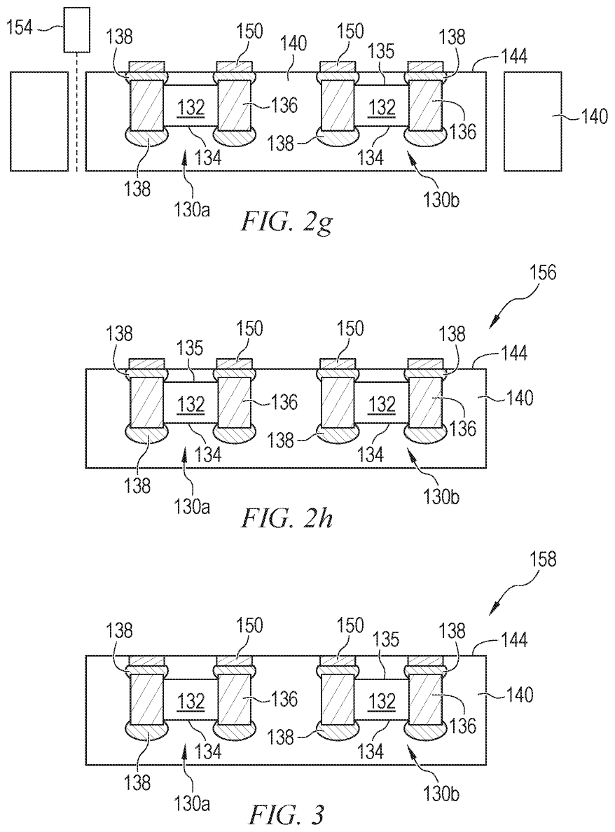

FIG. 2a shows a temporary substrate or carrier 120 containing sacrificial base material, such as silicon, polymer, beryllium oxide, glass, metal or other suitable low-cost, rigid material for structural support. Substrate 120 has major surface 122 and major surface 124, opposite surface 122. In one embodiment, carrier 120 is a support structure with a temporary bonding layer 126 formed over surface 122 of the carrier. Temporary bonding layer 126 can be a double-sided tape.

Discrete electrical components 130a-130b are disposed over surface 122 of substrate 120. Discrete electrical components 130a-130b can be a passive component, such as a resistor, capacitor, or inductor. Discrete electrical components 130a-130b can be an active component, such as a diode, transistor, or thyristor. Active-type discrete electrical components 130a-130b can be formed on a wafer, similar to FIG. 1a-1c. As an active example, a diode having an anode and cathode can be formed on substrate 132 with opposite type semiconductor layers, i.e. P-layer and N-layer. For example, a P-layer is formed within surface 134 and an N-layer is formed within surface 135 One electrical terminal 136 connects to the anode and the other electrical terminal 136 connects to the cathode. Passive-type discrete electrical components 130a-130b can be wound, layered, or otherwise fabricated with suitable electrical material. As a passive example, a capacitor is formed with a dielectric material layered between two metal plates or regions. One electrical terminal 136 connects to one metal plate and the other electrical terminal 136 connects to the other metal plate. Conductive material or solder 138 is deposited on electrical terminals 136. In one embodiment, conductive material 138 is an SnAg finish to enable even sputtering of the seed layer and plating Ni/Cu RDL over SnAg contact terminals.

Discrete electrical components 130a-130b are positioned over surface 122 of substrate 120 using a pick and place operation. Discrete electrical components 130a-130b are brought into contact with bonding layer 126. FIG. 2b illustrates discrete electrical components 130a-130b bonded to substrate 120. Conductive material 138 is partially embedded in bonding layer 126.

In FIG. 2c, encapsulant or molding compound 140 is deposited over and around discrete electrical components 130a-130b and substrate 120 using a paste printing, compressive molding, transfer molding, liquid encapsulant molding, vacuum lamination, spin coating, or other suitable applicator. Encapsulant 140 can be liquid or granular polymer composite material, such as epoxy resin with filler, epoxy acrylate with filler, or polymer with proper filler. Encapsulant 140 is non-conductive, provides structural support, and environmentally protects the semiconductor device from external elements and contaminants.

In FIG. 2d, carrier 120 and bonding layer 126 are removed by chemical etching, chemical mechanical polishing (CMP), mechanical peel-off, mechanical grinding, thermal bake, ultra-violet (UV) light, or wet stripping to expose conductive material 138 on electrical terminals 136.

In FIG. 2e, the assembly is inverted and surface 144 of encapsulant 140 undergoes a grinding operation with grinder 146 to planarize surface 144 and conductive material 138. Some encapsulant 140 remains over substrate 132.

In FIG. 2f, conductive layer 150 is formed over conductive material 138 of electrical terminals 136 using PVD, CVD, electrolytic plating, electroless plating process, or other suitable metal deposition process. Conductive layer 150 can be one or more layers of Al, Cu, Sn, Ni, Au, Ag, or other suitable electrically conductive material. Conductive layer 150 makes electrical connection to discrete electrical components 130a-130b. In one embodiment, conductive layer 150 is a build-up Cu pad.

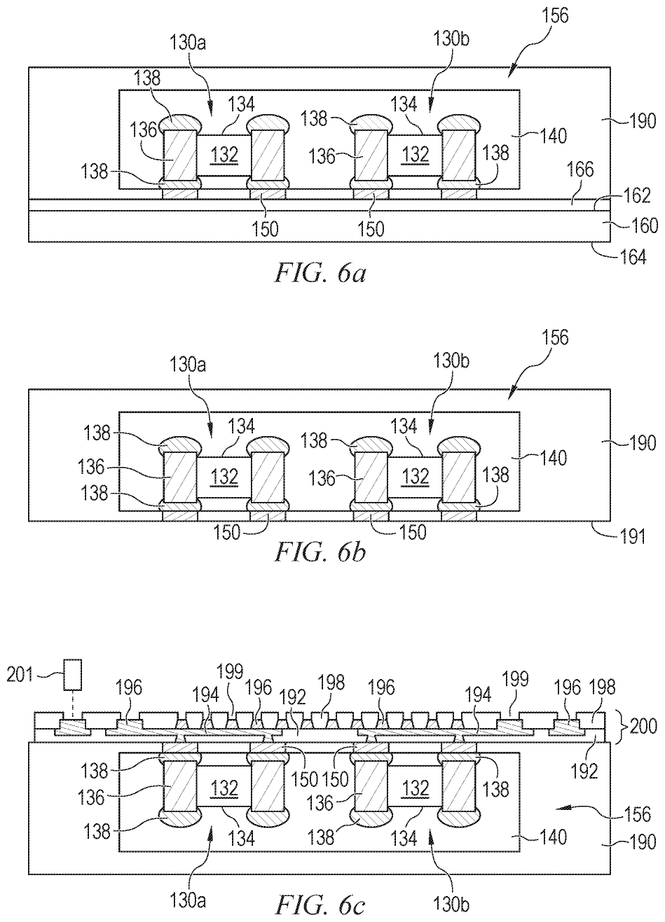

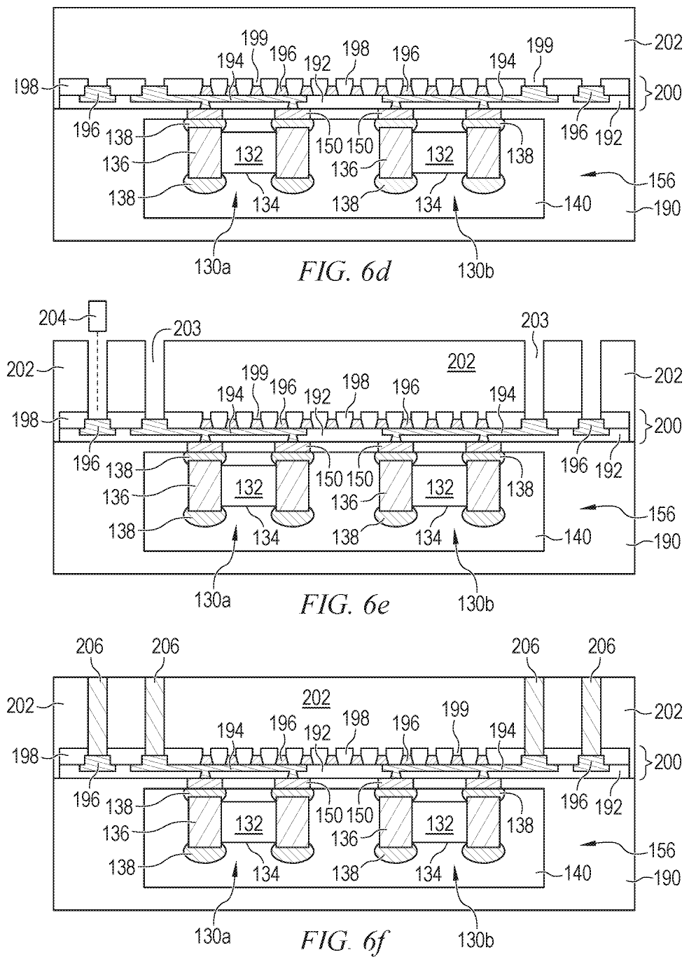

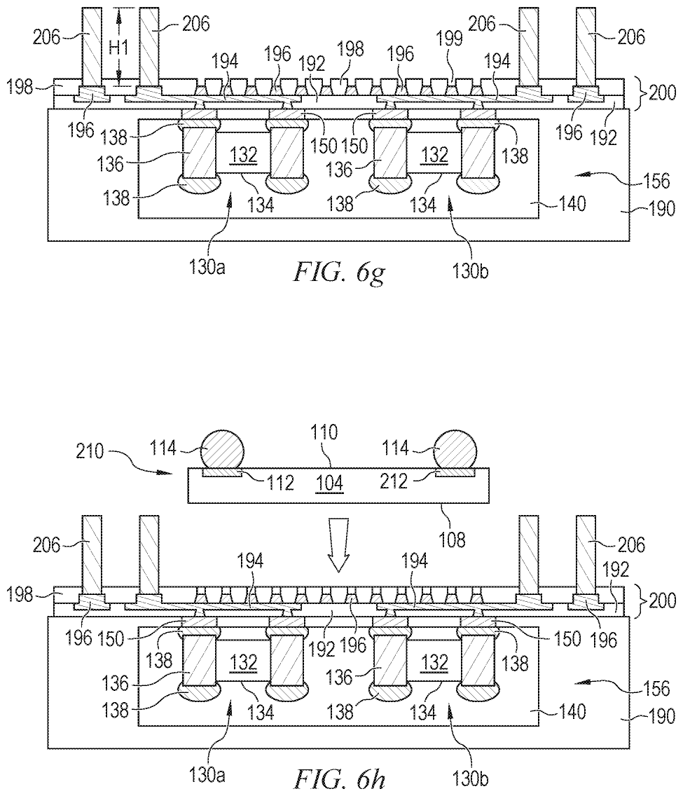

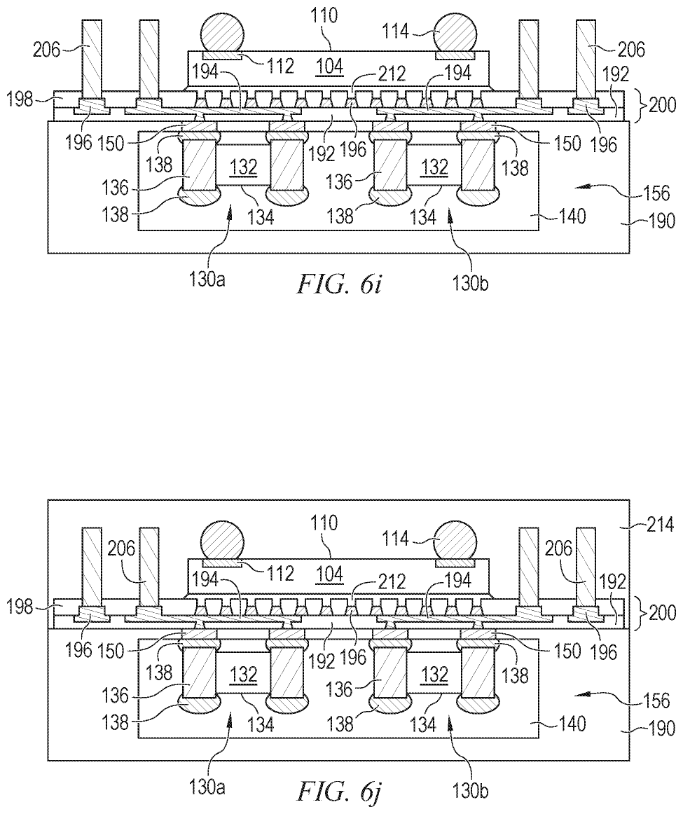

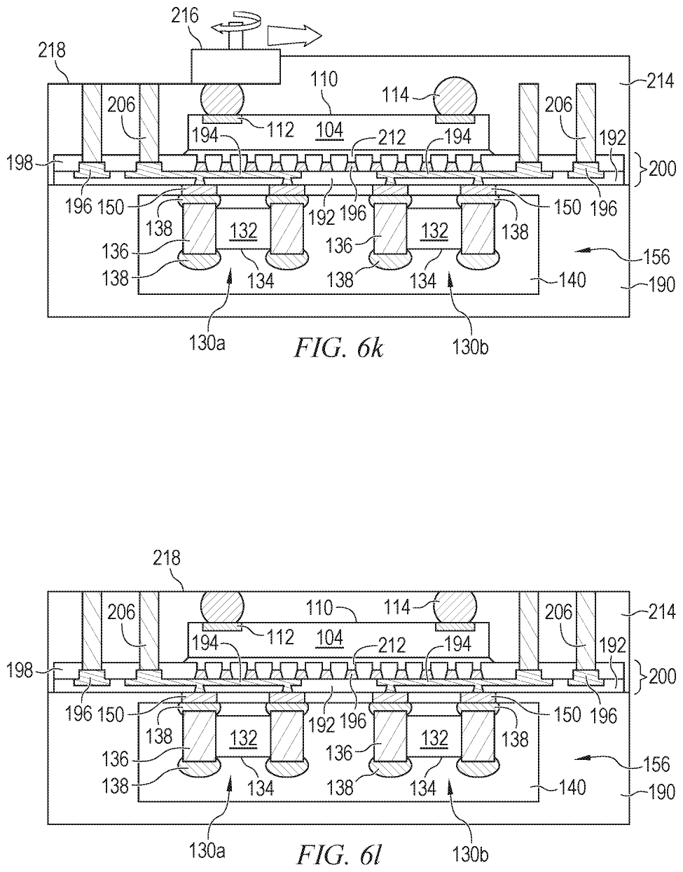

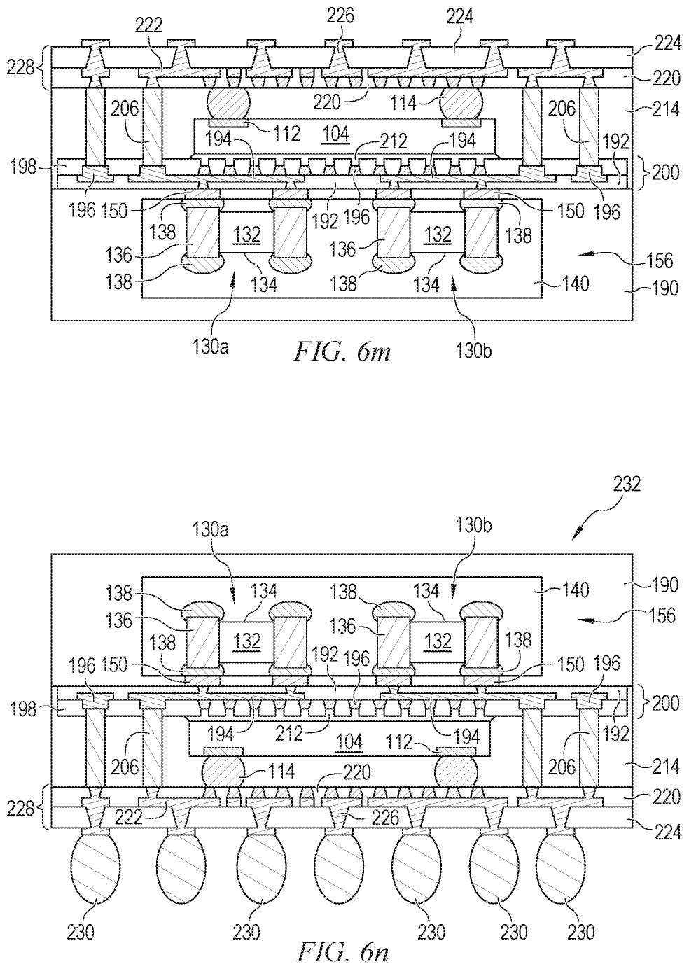

In FIG. 2g, encapsulant 140 is singulated using a saw blade or laser cutting tool 154. FIG. 2h shows discrete electrical components 130a-130b encapsulated in discrete component package 156 post singulation. Conductive layer 150 extends from encapsulant 140 in discrete component package 156. Discrete component package 156 contains discrete electrical components 130a-130b. Discrete electrical components 130a-130b are pre-molded or pre-encapsulated in that the discrete electrical components are embedded within encapsulant 140, prior to next level integration, as shown in FIGS. 6-8.

In another embodiment, discrete semiconductor package 158 in FIG. 3 shows conductive layer 150 coplanar with surface 144 of encapsulant 140. In this case, conductive layer 150 would be formed prior to encapsulation and grinder 146 in FIG. 2e would planarize surface 144 and conductive layer 150. Components having a similar function are assigned the same reference number. Discrete component package 158 contains discrete electrical components 130a-130b. Discrete electrical components 130a-130b are pre-molded or pre-encapsulated in that the discrete electrical components are embedded within encapsulant 140, prior to next level integration, as shown in FIGS. 6-8.

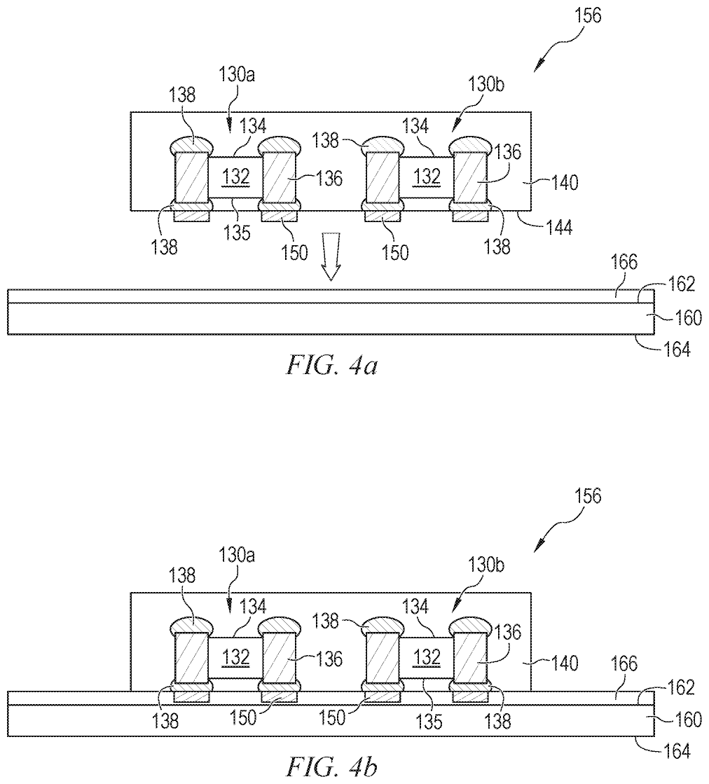

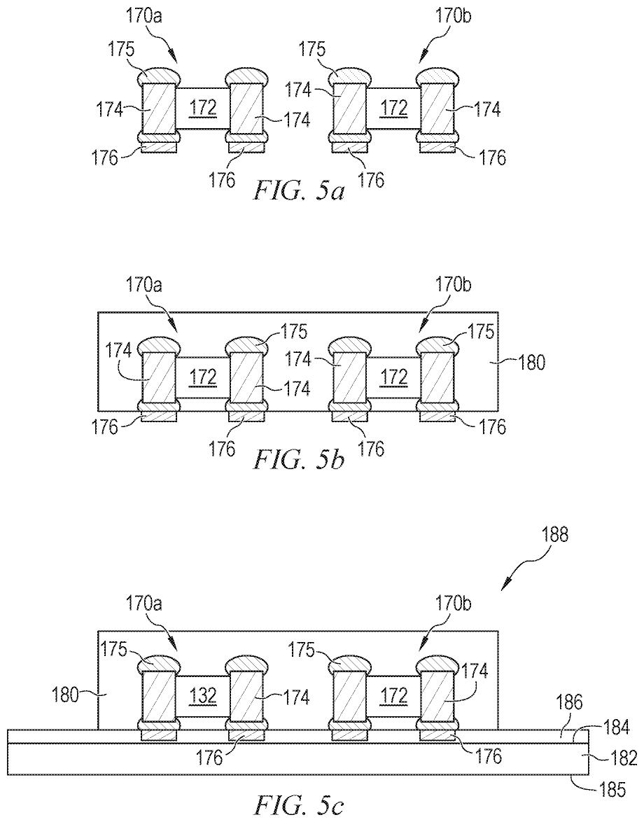

FIG. 4a shows a temporary substrate or carrier 160 containing sacrificial base material, such as silicon, polymer, beryllium oxide, glass, metal or other suitable low-cost, rigid material for structural support. Substrate 160 has major surface 162 and major surface 164, opposite surface 162. In one embodiment, carrier 160 is a support structure with a temporary bonding layer 166 formed over surface 162 of the carrier. Temporary bonding layer 166 can be a double-sided tape.

Discrete component package 156 from FIG. 2h or discrete components package 158 from FIG. 3 is disposed over surface 162 of substrate 160 using a pick and place operation. Discrete component package 156 is brought into contact with bonding layer 166. FIG. 4b illustrates discrete component package 156 bonded to substrate 160. Conductive layer 150 is partially embedded in bonding layer 166.

In another embodiment, FIG. 5a shows discrete electrical components 170a-170b formed similar to FIG. 2a or other suitable fabrication process. Discrete electrical components 170a-170b have functional area 172, i.e. active or passive device, electrical terminals 174 and conductive material or solder 175 deposited on the electrical terminals. In one embodiment, conductive material 175 is an SnAg finish to enable even sputtering of the seed layer and plating Ni/Cu RDL over SnAg contact terminals.

Conductive layer 176 is formed over conductive material 175 of electrical terminals 174 using PVD, CVD, electrolytic plating, electroless plating process, or other suitable metal deposition process. Conductive layer 176 can be one or more layers of Al, Cu, Sn, Ni, Au, Ag, or other suitable electrically conductive material. Conductive layer 176 makes electrical connection to discrete electrical components 170a-170b.

In FIG. 5b, encapsulant or molding compound 180 is deposited over and around discrete electrical components 170a-170b using a paste printing, compressive molding, transfer molding, liquid encapsulant molding, vacuum lamination, spin coating, or other suitable applicator.

FIG. Sc shows a temporary substrate or carrier 182 containing sacrificial base material, such as silicon, polymer, beryllium oxide, glass, metal or other suitable low-cost, rigid material for structural support. Substrate 182 has major surface 184 and major surface 185, opposite surface 184. In one embodiment, carrier 182 is a support structure with a temporary bonding layer 186 formed over surface 184 of the carrier. Temporary bonding layer 186 can be a double-sided tape.

In FIG. 5c, discrete electrical components 170a-170b are positioned over surface 184 of substrate 182 using a pick and place operation, similar to FIGS. 4a-4b. Discrete electrical components 170a-170b are brought into contact with bonding layer 186. Conductive layer 176 is partially embedded in bonding layer 186. Discrete component package 188 contains discrete electrical components 170a-170b. Discrete electrical components 170a-170b are pre-molded or pre-encapsulated in that the discrete electrical components are embedded within encapsulant 180, prior to next level integration, as shown in FIGS. 6-8.

In FIG. 6a, encapsulant or molding compound 190 is deposited over and around discrete component package 156 from FIG. 2h, or discrete component package 158 from FIG. 3, or discrete component package 188 from FIG. 5c, using a paste printing, compressive molding, transfer molding, liquid encapsulant molding, vacuum lamination, spin coating, or other suitable applicator. Encapsulant 190 can be liquid or granular polymer composite material, such as epoxy resin with filler, epoxy acrylate with filler, or polymer with proper filler. Encapsulant 190 is non-conductive, provides structural support, and environmentally protects the semiconductor device from external elements and contaminants.

The following disclosure is described in terms of discrete component package 156 from FIG. 2h, although the text is applicable to discrete component package 158 from FIG. 3 and discrete component package 188 from FIG. 5c. In FIG. 6b, carrier 160 and bonding layer 166 are removed by chemical etching, CMP, mechanical peel-off, mechanical grinding, thermal bake, UV light, or wet stripping to expose conductive layer 150. Encapsulant 190 undergoes an optional grinding operation to planarize surface 191 and conductive layer 150. Some encapsulant 190 remains over substrate 132.

In FIG. 6c, the assembly is inverted and an insulating or passivation layer 192 is formed over surface 191 and conductive layer 150 using PVD, CVD, printing, lamination, spin coating, spray coating, sintering or thermal oxidation. Insulating layer 192 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Portions of insulating layer 192 are removed using an etching process or laser direct ablation (LDA) to form openings or vias extending to conductive layer 150 for further electrical interconnect.

A conductive layer 194 is formed over insulating layer 192 and into the vias to conductive layer 150 using PVD, CVD, electrolytic plating, electroless plating process, or other suitable metal deposition process. Conductive layer 194 can be one or more layers of Al, Cu, Sn, Ni, Au, Ag, or other suitable electrically conductive material. Conductive layer 194 extends through openings in insulating layer 192 to conductive layer 150 to make electrical connection to discrete electrical components 130a-130b.

A conductive layer 196 is formed over insulating layer 192 and conductive layer 194 using PVD, CVD, electrolytic plating, electroless plating process, or other suitable metal deposition process. Conductive layer 196 can be one or more layers of Al, Cu, Sn, Ni, Au, Ag, or other suitable electrically conductive material.

An insulating or passivation layer 198 is formed over insulating layer 192 and conductive layers 194 and 196 using PVD, CVD, printing, lamination, spin coating, spray coating, sintering or thermal oxidation. Insulating layer 198 contains one or more layers of SiO2, Si3N4, SiON, Ta2O5, Al2O3, solder resist, polyimide, BCB, PBO, and other material having similar insulating and structural properties. Portions of insulating layer 198 are removed using an etching process or LDA to form openings or vias 199 extending to conductive layer 196 for further electrical interconnect, such as the multi-layer RDL buildup structures or interconnect bumps. Insulating layers 192 and 198 provide isolation around conductive layers 194 and 196. Conductive layers 194 and 196, in combination with insulating layers 192 and 198, constitute RDL 200. RDL 200 has fine line spacing, less than 8/8 μm.

In FIG. 6d, a solder resist or photoresist layer 202 is formed over RDL 200. In FIG. 6e, a plurality of openings 203 is formed in solder resist/photoresist 202 using an etching process or LDA by way of laser 204.

In FIG. 6f, openings 203 are filled with conductive material to form conductive columns or pillars 206. In FIG. 6g, the remaining solder resist/photoresist 202 is removed leaving conductive columns or pillars or post 206. Conductive columns or pillars or posts 206 can be Al, Cu, Sn, Ni, Au, Ag, multi-layer combined or other suitable electrically conductive material. Conductive pillars 206 can have a height Hi of 100.0 μm to compensate for thickness variation in different technologies, such as surface mount and flipchip.

In FIG. 6h, electrical component 210 is disposed over RDL 200 between conductive pillars 206 with bumps 114 oriented away from the RDL. Electrical component 210 can be semiconductor die 104 from FIG. 1c with back surface 108 oriented toward RDL 200. Alternatively, electrical component 210 can include other semiconductor die, semiconductor packages, surface mount devices, RF components, discrete electrical devices, or integrated passive devices (IPD).

Electrical component 210 is positioned over RDL 200 using a pick and place operation. Electrical component 210 is brought into contact with insulating layer 198 and secured with an adhesive or other bonding layer 212. FIG. 6i illustrates electrical component 210 bonded to RDL 200 adhesive or other bonding layer 212.

In FIG. 6j, encapsulant or molding compound 214 is deposited over and around electrical component 210, conductive pillars 206, and RDL 200 using a paste printing, compressive molding, transfer molding, liquid encapsulant molding, vacuum lamination, spin coating, or other suitable applicator. Encapsulant 214 can be liquid or granular polymer composite material, such as epoxy resin with filler, epoxy acrylate with filler, or polymer with proper filler. Encapsulant 214 is non-conductive, provides structural support, and environmentally protects the semiconductor device from external elements and contaminants.

In FIG. 6k, encapsulant 214 undergoes a grinding operation with grinder 216 to planarize surface 218 and expose conductive pillars 206 and bumps 114. Some encapsulant 214 remains over electrical component 210. FIG. 6l shows coplanar surface 218 and exposed conductive pillars 206 and bumps 114.

In FIG. 6m, insulating or passivation layer 220 is formed over surface 218 using PVD, CVD, printing, lamination, spin coating, spray coating, sintering or thermal oxidation. Insulating layer 220 contains one or more layers of SiO2, Si3N4, SiON, Ta2O5, Al2O3, solder resist, polyimide, BCB, PBO, and other material having similar insulating and structural properties. Portions of insulating layer 202 are removed using an etching process or LDA to form openings or vias extending to conductive pillars 206 and bumps 114 for further electrical interconnect.

A conductive layer 222 is formed over insulating layer 220 and into the vias to conductive pillars 206 and bumps 114 using PVD, CVD, electrolytic plating, electroless plating process, or other suitable metal deposition process. Conductive layer 222 can be one or more layers of Al, Cu, Sn, Ni, Au, Ag, or other suitable electrically conductive material. Conductive layer 222 extends through openings in insulating layer 220 to conductive pillars 206 and bumps 114 to make electrical connection to electrical component 210, RDL 200, and discrete electrical components 130a-130b.

An insulating or passivation layer 224 is formed over insulating layer 220 and conductive layer 222 using PVD, CVD, printing, lamination, spin coating, spray coating, sintering or thermal oxidation. Insulating layer 224 contains one or more layers of SiO2, Si3N4, SiON, Ta2O5, Al2O3, solder resist, polyimide, BCB, PBO, and other material having similar insulating and structural properties. Portions of insulating layer 224 are removed using an etching process or LDA to form openings or vias extending to conductive layer 222 for further electrical interconnect.

A conductive layer 226 is formed over insulating layer 224 and conductive layer 222 using PVD, CVD, electrolytic plating, electroless plating process, or other suitable metal deposition process. Conductive layer 226 can be one or more layers of Al, Cu, Sn, Ni, Au, Ag, or other suitable electrically conductive material. Conductive layer 226 extends through openings in insulating layer 224 to conductive pillars 206 and bumps 114 to make electrical connection to electrical component 210, RDL 200, and discrete electrical components 130a-130b. Insulating layers 220 and 224 provide isolation around conductive layers 222 and 226. Conductive layers 222 and 226, in combination with insulating layers 220 and 224, constitutes RDL 228 as it redistributes the electrical signal across and over electrical component 210, encapsulant 214, and conductive pillars 206. Portions of RDL 200 and 228 can be electrically common or electrically isolated depending on the design and function of electrical component 210, discrete electrical components 130a-130b, and other electrical components attached thereto. RDL 228 has fine line spacing, less than 8/8 μm.

In FIG. 6n, an electrically conductive bump material is deposited over conductive layer 226 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 226 using a suitable attachment or bonding process. In one embodiment, the bump material is reflowed by heating the material above its melting point to form balls or bumps 230. In another embodiment, bump 230 is formed over a UBM having a wetting layer, barrier layer, and adhesive layer. Bump 230 can also be compression bonded or thermocompression bonded to conductive layer 226. Bump 230 represents one type of interconnect structure that can be formed over conductive layer 226. The interconnect structure can also use conductive paste, stud bump, micro bump, or other electrical interconnect.

The combination of discrete electrical components 130a-130b, encapsulant 140, encapsulant 190, RDL 200, conductive pillars 206, electrical component 210, encapsulant 214, and RDL 228 constitute fan-out wafer level package (FOWLP) or embedded wafer level ball grid array (eWLB) 232. Package 232 has electrical interconnection between discrete electrical components 130a-130b and electrical component 210 through RDL 200, conductive pillars 206, and RDL 228, as well as external interconnect with bumps 230. Package 232 has no through silicon vias, potentially damaging to electrical component 210. Package 232 has a thin profile, less than 1.0 mm, and RDLs 200 and 228 have fine line spacing, less than 8/8 μm. Discrete electrical components 130a-130b are pre-molded and embedded providing protection with multiple encapsulant layers on all sides.

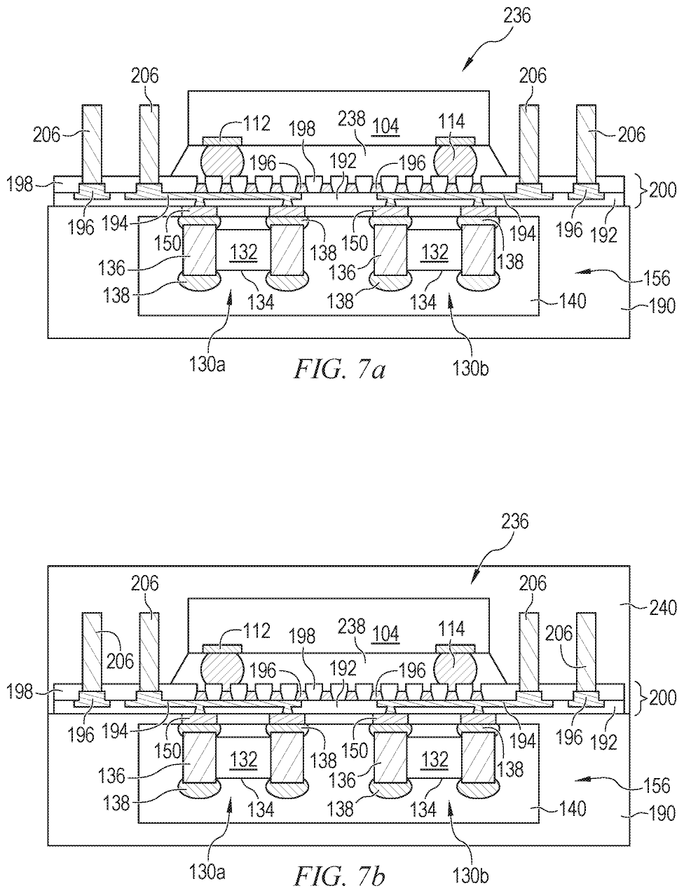

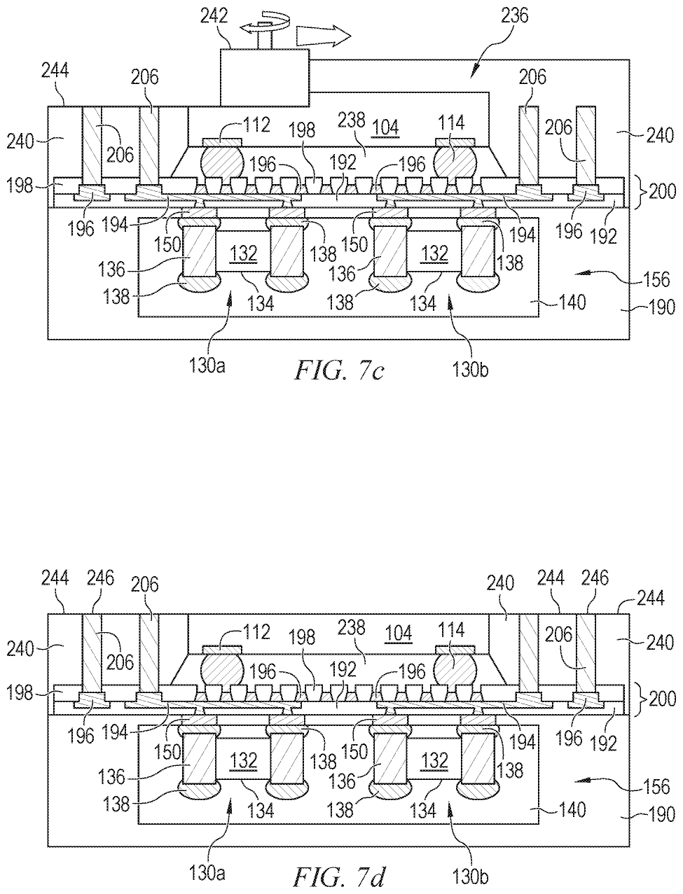

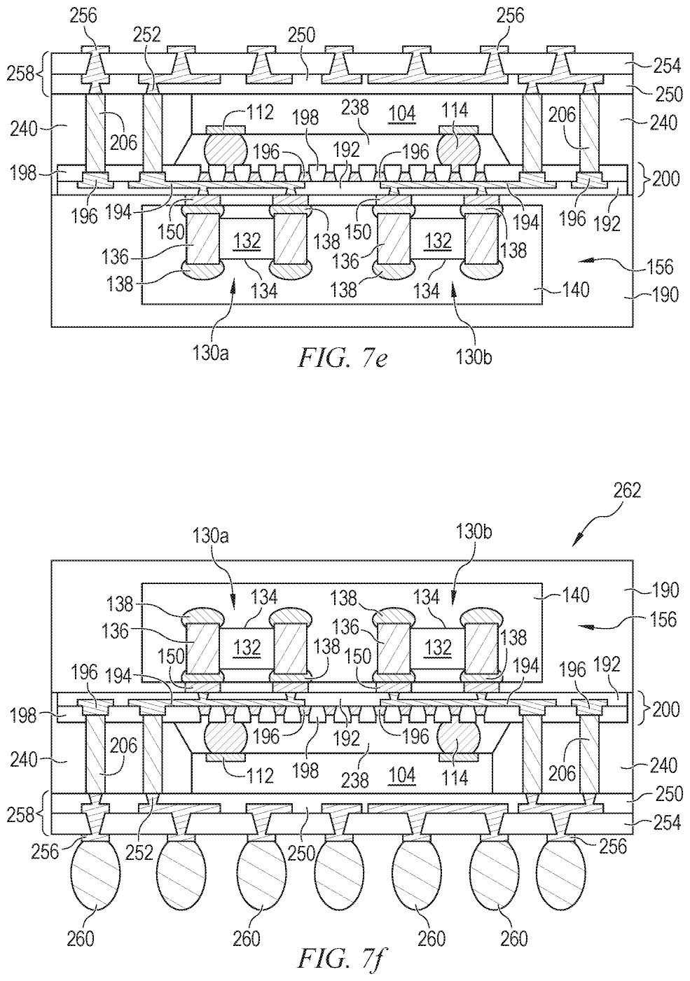

In another embodiment, continuing from FIG. 6g, electrical component 236 is disposed over RDL 200 between conductive pillars 206 with bumps 114 oriented toward the RDL, as shown in FIG. 7a. Components having a similar function are assigned the same reference number. Electrical component 236 can be semiconductor die 104 from FIG. 1c with bumps 114 oriented toward RDL 200. Alternatively, electrical component 236 can include other semiconductor die, semiconductor packages, surface mount devices, RF components, discrete electrical devices, or IPD.

Electrical component 236 is positioned over RDL 200 using a pick and place operation, similar to FIGS. 6h-6i. Bumps 114 of electrical component 236 are brought into contact with conductive layer 196. Bumps 114 are reflowed to form a secure mechanical and electrical connection to conductive layer 196 of RDL 200. An underfill material 238, such as epoxy resin, is deposited under electrical component 236.

In FIG. 7b, encapsulant or molding compound 240 is deposited over and around electrical component 236, conductive pillars 206, and RDL 200 using a paste printing, compressive molding, transfer molding, liquid encapsulant molding, vacuum lamination, spin coating, or other suitable applicator. Encapsulant 240 can be liquid or granular polymer composite material, such as epoxy resin with filler, epoxy acrylate with filler, or polymer with proper filler. Encapsulant 240 is non-conductive, provides structural support, and environmentally protects the semiconductor device from external elements and contaminants.

In FIG. 7c, encapsulant 240 undergoes a grinding operation with grinder 242 to planarize surface 244 and expose conductive pillars 206 and a back surface of electrical component 236. FIG. 7d shows surface 244 coplanar with surface 246 of the exposed conductive pillars 206.

In FIG. 7e, insulating or passivation layer 250 is formed over surface 244 using PVD, CVD, printing, lamination, spin coating, spray coating, sintering or thermal oxidation. Insulating layer 250 contains one or more layers of SiO2, Si3N4, SiON, Ta2O5, Al2O3, solder resist, polyimide, BCB, PBO, and other material having similar insulating and structural properties. Portions of insulating layer 250 are removed using an etching process or LDA to form openings or vias extending to conductive pillars 206 for further electrical interconnect.

A conductive layer 252 is formed over insulating layer 250 and into the vias to conductive pillars 206 using PVD, CVD, electrolytic plating, electroless plating process, or other suitable metal deposition process. Conductive layer 252 can be one or more layers of Al, Cu, Sn, Ni, Au, Ag, or other suitable electrically conductive material. Conductive layer 252 extends through openings in insulating layer 250 to conductive pillars 206 to make electrical connection to electrical component 236, RDL 200, and discrete electrical components 130a-130b.

An insulating or passivation layer 254 is formed over insulating layer 250 and conductive layer 252 using PVD, CVD, printing, lamination, spin coating, spray coating, sintering or thermal oxidation. Insulating layer 254 contains one or more layers of SiO2, Si3N4, SiON, Ta2O5, Al2O3, solder resist, polyimide, BCB, PBO, and other material having similar insulating and structural properties. Portions of insulating layer 254 are removed using an etching process or LDA to form openings or vias extending to conductive layer 252 for further electrical interconnect.

A conductive layer 256 is formed over insulating layer 254 and conductive layer 252 using PVD, CVD, electrolytic plating, electroless plating process, or other suitable metal deposition process. Conductive layer 256 can be one or more layers of Al, Cu, Sn, Ni, Au, Ag, or other suitable electrically conductive material. Conductive layer 256 extends through openings in insulating layer 254 to conductive pillars 206 to make electrical connection to electrical component 236, RDL 200, and discrete electrical components 130a-130b. Insulating layers 250 and 254 provide isolation around conductive layers 252 and 256. Conductive layers 252 and 256, in combination with insulating layers 250 and 254, constitutes RDL 258 as it redistributes the electrical signal across and over electrical component 236, encapsulant 240, and conductive pillars 206. Portions of RDL 200 and 258 can be electrically common or electrically isolated depending on the design and function of electrical component 236, discrete electrical components 130a-130b, and other electrical components attached thereto. RDL 258 has fine line spacing, less than 8/8 μm.

In FIG. 7f, an electrically conductive bump material is deposited over conductive layer 256 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 256 using a suitable attachment or bonding process. In one embodiment, the bump material is reflowed by heating the material above its melting point to form balls or bumps 260. In another embodiment, bump 260 is formed over a UBM having a wetting layer, barrier layer, and adhesive layer. Bump 260 can also be compression bonded or thermocompression bonded to conductive layer 256. Bump 260 represents one type of interconnect structure that can be formed over conductive layer 256. The interconnect structure can also use conductive paste, stud bump, micro bump, or other electrical interconnect.

The combination of discrete electrical components 130a-130b, encapsulant 140, encapsulant 190, RDL 200, conductive pillars 206, electrical component 236, encapsulant 240, and RDL 258 constitute FoWLP or eWLB 262. Package 262 has electrical interconnection between discrete electrical components 130a-130b and electrical component 236 through RDL 200, conductive pillars 206, and RDL 258, as well as external interconnect with bumps 260. Package 262 has no through silicon vias, potentially damaging electrical component 236. Package 262 has a thin profile, less than 1.0 mm, and RDLs 200 and 258 have fine line spacing, less than 8/8 μm. Discrete electrical components 130a-130b are pre-molded and embedded providing protection with multiple encapsulant layers on all sides.

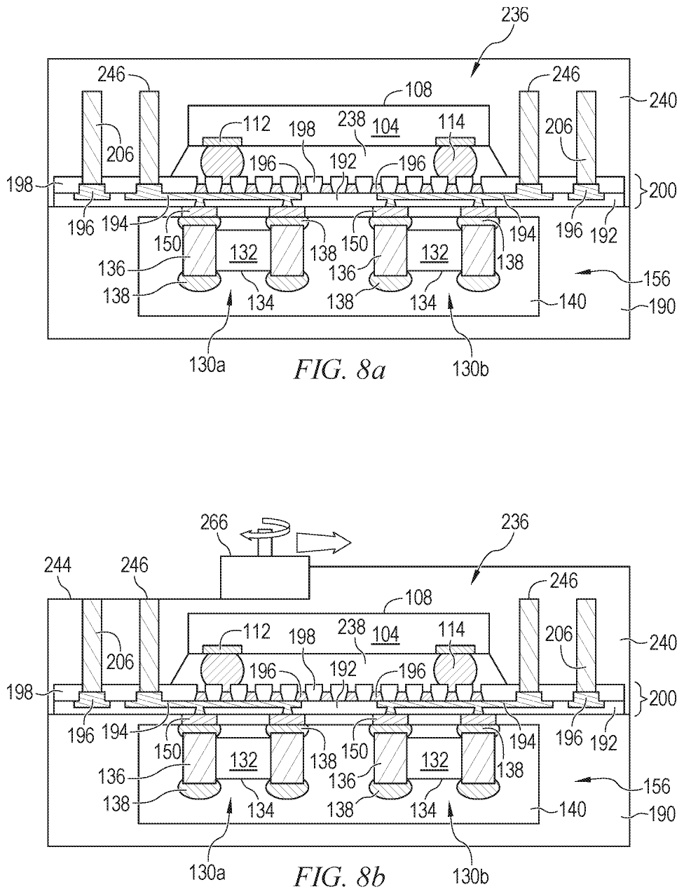

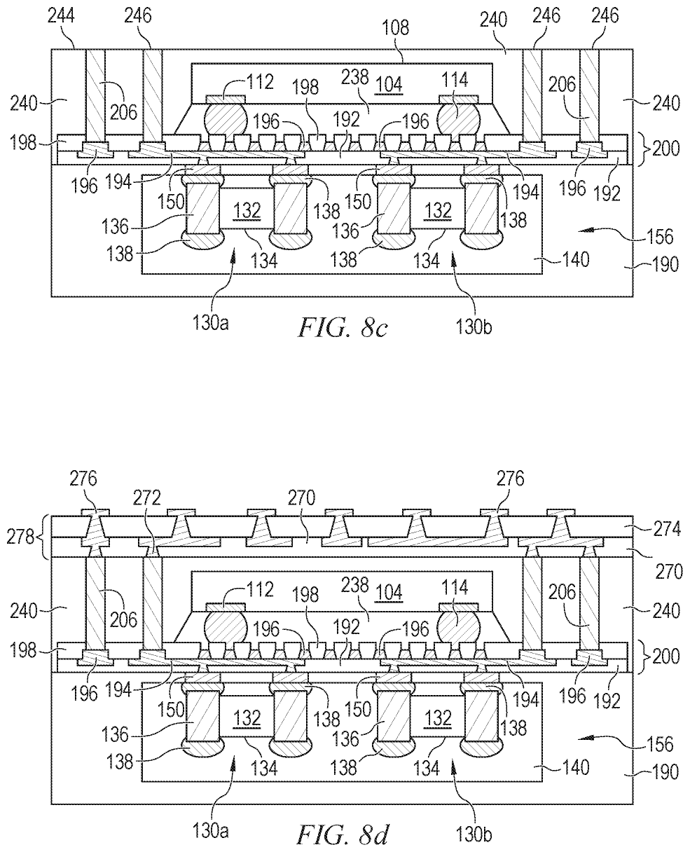

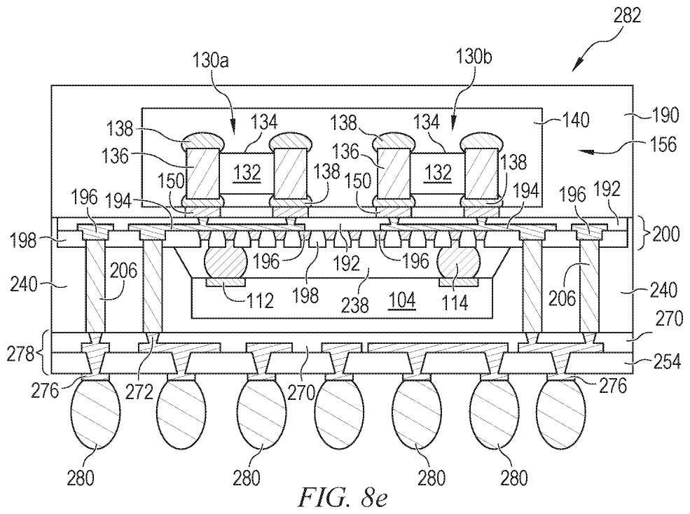

In another embodiment, continuing from FIG. 7b, top surface 246 of conductive pillars 206 extend above back surface 108 of electrical component 236, as shown in FIG. 8a. In FIG. 8b, encapsulant 240 undergoes a grinding operation with grinder 266 to planarize surface 244 and expose conductive pillars 206. FIG. 8c shows surface 244 coplanar with surface 246 of the exposed conductive pillars 206. A portion of encapsulant 240 remains over back surface 108 of electrical component 236.

In FIG. 8d, insulating or passivation layer 270 is formed over surface 244 using PVD, CVD, printing, lamination, spin coating, spray coating, sintering or thermal oxidation. Insulating layer 270 contains one or more layers of SiO2, Si3N4, SiON, Ta2O5, Al2O3, solder resist, polyimide, BCB, PBO, and other material having similar insulating and structural properties. Portions of insulating layer 270 are removed using an etching process or LDA to form openings or vias extending to conductive pillars 206 for further electrical interconnect.

A conductive layer 272 is formed over insulating layer 270 and into the vias to conductive pillars 206 using PVD, CVD, electrolytic plating, electroless plating process, or other suitable metal deposition process. Conductive layer 272 can be one or more layers of Al, Cu, Sn, Ni, Au, Ag, or other suitable electrically conductive material. Conductive layer 272 extends through openings in insulating layer 270 to conductive pillars 206 to make electrical connection to electrical component 236, RDL 200, and discrete electrical components 130a-130b.

An insulating or passivation layer 274 is formed over insulating layer 270 and conductive layer 272 using PVD, CVD, printing, lamination, spin coating, spray coating, sintering or thermal oxidation. Insulating layer 274 contains one or more layers of SiO2, Si3N4, SiON, Ta2O5, Al2O3, solder resist, polyimide, BCB, PBO, and other material having similar insulating and structural properties. Portions of insulating layer 274 are removed using an etching process or LDA to form openings or vias extending to conductive layer 272 for further electrical interconnect.

A conductive layer 276 is formed over insulating layer 274 and conductive layer 272 using PVD, CVD, electrolytic plating, electroless plating process, or other suitable metal deposition process. Conductive layer 276 can be one or more layers of Al, Cu, Sn, Ni, Au, Ag, or other suitable electrically conductive material. Conductive layer 276 extends through openings in insulating layer 274 to conductive pillars 206 to make electrical connection to electrical component 236, RDL 200, and discrete electrical components 130a-130b. Insulating layers 270 and 274 provide isolation around conductive layers 272 and 276. Conductive layers 272 and 276, in combination with insulating layers 270 and 274, constitute RDL 278 as it redistributes the electrical signal across and over electrical component 236, encapsulant 240, and conductive pillars 206. Portions of RDL 200 and 278 can be electrically common or electrically isolated depending on the design and function of electrical component 236, discrete electrical components 130a-130b, and other electrical components attached thereto. RDL 278 has fine line spacing, less than 8/8 μm.

In FIG. 8e, an electrically conductive bump material is deposited over conductive layer 276 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 276 using a suitable attachment or bonding process. In one embodiment, the bump material is reflowed by heating the material above its melting point to form balls or bumps 280. In another embodiment, bump 280 is formed over a UBM having a wetting layer, barrier layer, and adhesive layer. Bump 280 can also be compression bonded or thermocompression bonded to conductive layer 276. Bump 280 represents one type of interconnect structure that can be formed over conductive layer 276. The interconnect structure can also use conductive paste, stud bump, micro bump, or other electrical interconnect.

The combination of discrete electrical components 130a-130b, encapsulant 140, encapsulant 190, RDL 200, conductive pillars 206, electrical component 236, encapsulant 240, and RDL 278 constitute FoWLP or eWLB 282. Package 282 has electrical interconnection between discrete electrical components 130a-130b and electrical component 236 through RDL 200, conductive pillars 206, and RDL 278, as well as external interconnect with bumps 280. Package 282 has no through silicon vias, potentially damaging electrical component 236. Package 282 has a thin profile, less than 1.0 mm, and RDLs 200 and 278 have fine line spacing, less than 8/8 μm. Discrete electrical components 130a-130b are pre-molded and embedded providing protection with multiple encapsulant layers on all sides.

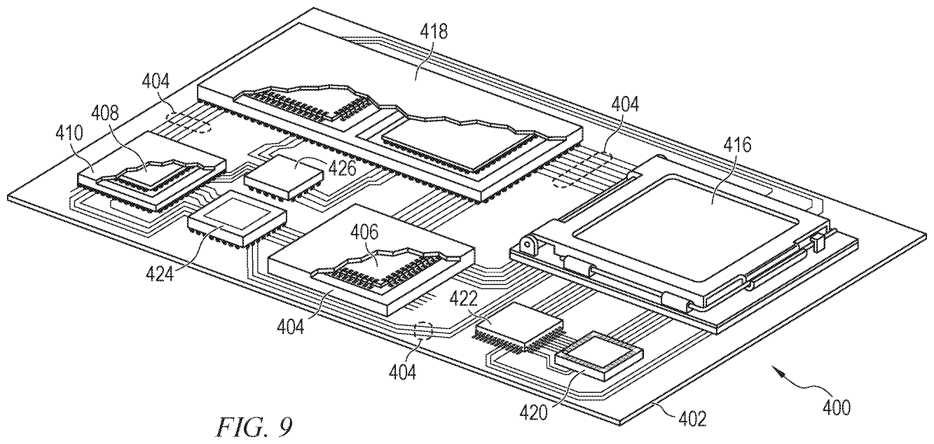

FIG. 9 illustrates electrical device 400 having a chip carrier substrate or PCB 402 with a plurality of semiconductor packages disposed on a surface of PCB 402, including FoWLP 232, FoWLP 262, and FoWLP 282. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 9, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a pre-molded discrete electrical component;
a first encapsulant deposited over the pre-molded discrete electrical component;
a first conductive layer formed over the first encapsulant and pre-molded discrete electrical component;
an electrical component disposed over the first conductive layer;
a second encapsulant deposited over the electrical component and first conductive layer; and
a second conductive layer formed over the second encapsulant.

2. The semiconductor device of claim 1, further including a conductive pillar formed between the first conductive layer and second conductive layer through the second encapsulant.

3. The semiconductor device of claim 1, wherein the pre-molded discrete electrical component includes:
a discrete component; and
a third encapsulant deposited around the discrete component.

4. The semiconductor device of claim 3, wherein the discrete component includes:
a discrete device;
an electrical terminal coupled to the discrete device;
a finish formed over the electrical terminal; and
a third conductive layer formed over the finish.

5. The semiconductor device of claim 1, wherein an interconnect structure formed on the electrical component is oriented toward the first conductive layer.

6. The semiconductor device of claim 1, wherein an interconnect structure formed on the electrical component is oriented toward the second conductive layer.

7. A semiconductor device, comprising:
a semiconductor package; and
a pre-molded discrete electrical component disposed over the semiconductor package.

8. The semiconductor device of claim 7, wherein the semiconductor package includes:
a first encapsulant deposited over the pre-molded discrete electrical component;
a first conductive layer formed over the first encapsulant and pre-molded discrete electrical component;
an electrical component disposed over the first conductive layer;
a second encapsulant deposited over the electrical component and first conductive layer; and
a second conductive layer formed over the second encapsulant.

9. The semiconductor device of claim 8, further including a conductive pillar formed between the first conductive layer and second conductive layer through the second encapsulant.

10. The semiconductor device of claim 8, wherein an interconnect structure formed on the electrical component is oriented toward the first conductive layer.

11. The semiconductor device of claim 8, wherein an interconnect structure formed on the electrical component is oriented toward the second conductive layer.

12. The semiconductor device of claim 7, wherein the pre-molded discrete electrical component includes:
a discrete component; and
an encapsulant deposited around the discrete component.

13. The semiconductor device of claim 12, wherein the discrete component includes:
a discrete device;
an electrical terminal coupled to the discrete device;
a finish formed over the electrical terminal; and
a conductive layer formed over the finish.

14. A method of making a semiconductor device, comprising:
providing a pre-molded discrete electrical component;
depositing a first encapsulant over the pre-molded discrete electrical component;
forming a first conductive layer over the first encapsulant and pre-molded discrete electrical component;
disposing an electrical component over the first conductive layer;
depositing a second encapsulant over the electrical component and first conductive layer; and
forming a second conductive layer over the second encapsulant.

15. The method of claim 14, further including forming a conductive pillar between the first conductive layer and second conductive layer through the second encapsulant.

16. The method of claim 14, wherein the pre-molded discrete electrical component includes:
providing a discrete component; and
depositing a third encapsulant around the discrete component.

17. The method of claim 16, wherein the discrete component includes:
providing a discrete device;
forming an electrical terminal for the discrete device;
forming a finish over the electrical terminal; and
forming a third conductive layer over the finish.

18. The method of claim 14, further including orienting an interconnect structure of the electrical component toward the first conductive layer.

19. The method of claim 14, further including orienting an interconnect structure of the electrical component toward the second conductive layer.

20. A method of making a semiconductor device, comprising:
providing a pre-molded discrete electrical component; and
forming a semiconductor package with the pre-molded discrete electrical component disposed over the semiconductor package.

21. The method of claim 20, wherein forming the semiconductor package includes:
depositing a first encapsulant over the pre-molded discrete electrical component;
forming a first conductive layer over the first encapsulant and pre-molded discrete electrical component;
disposing an electrical component over the first conductive layer;
depositing a second encapsulant over the electrical component and first conductive layer; and
forming a second conductive layer over the second encapsulant.

22. The method of claim 21, further including forming a conductive pillar between the first conductive layer and second conductive layer through the second encapsulant.

23. The method of claim 21, further including orienting an interconnect structure of the electrical component toward the first conductive layer.

24. The method of claim 21, further including orienting an interconnect structure of the electrical component toward the second conductive layer.

25. The method of claim 20, wherein providing the pre-molded discrete electrical component includes:
providing a discrete component; and
depositing an encapsulant around the discrete component.
